(19) United States
(12) Patent Application Publication
(10) Pub. No.: US 2025/0284210 A1
(43) Pub. Date: Sep. 11, 2025

(54) EXPOSURE APPARATUS AND CONTROL METHOD THEREOF

(71) Applicant: NANYA TECHNOLOGY CORPORATION, New Taipei city (TW)

(72) Inventor: Jung Tzu PENG, New Taipei City (TW)

(21) Appl. No.: 18/599,761

(22) Filed: Mar. 8, 2024

(51) Int. Cl. G03F 7/00; H01L 21/683

(52) U.S. Cl. CPC G03F 7/707; G03F 7/70508; G03F 7/70525; G03F 7/70775; H01L 21/6838

(57) ABSTRACT

An exposure apparatus includes an exposure chuck and a wafer height fine-tuning device. The exposure chuck is used to fix a wafer, and the wafer height fine-tuning device is disposed between the exposure chuck and the wafer to adjust heights of a local area of the wafer. In addition, an exposure apparatus control method is also disclosed herein.

### BACKGROUND

### Field of Invention

The present disclosure relates to an exposure apparatus and a control method thereof. More particularly, the present disclosure relates to a semiconductor device exposure apparatus and a control method thereof.

### Description of Related Art

Due to the rapid development of integrated circuits, minimizing the device dimension and increasing the integration level have become the mainstream in the semiconductor industry. Generally, a semiconductor device is fabricated by performing a series of processes including deposition processes, photolithography processes, etching processes, and ion implantation processes. The key technology to decide the critical dimension (CD) is in photolithography and etching. A typical photolithography process is conducted with a photolithography tool including a stepper or a scanner. The photolithography process normally includes coating a photoresist layer on a material layer to be patterned with a coater unit of the track, partially exposing the photo resist layer by the stepper or the scanner, post-exposure baking (PEB) the exposed photoresist layer with a PEB unit, and developing the exposed photoresist layer with a developer unit. Thereafter, an etching process is preformed to the material layer by using the developed photoresist layer as a mask, so as to transfer the patterns from the developed photoresist layer to the material layer.

However, as the exposure accuracy requirements are getting higher and higher, there is a need to improve the exposure accuracy so as to improve the quality and yield of semiconductor devices.

### SUMMARY

The summary of the present invention is intended to provide a simplified description of the disclosure to enable readers to have a basic understanding of the disclosure. The summary of the present invention is not a complete overview of the disclosure, and it is not intended to point out the importance of the embodiments/key elements of the present invention or define the scope of the invention.

One objective of the embodiments of the present invention is to provide an exposure apparatus and a control method thereof to improve the quality and yield of the semiconductor devices.

To achieve these and other advantages and in accordance with the objective of the embodiments of the present invention, as the embodiment broadly describes herein, the embodiments of the present disclosure provides an exposure apparatus including an exposure chuck and a wafer height fine-tuning device. The exposure chuck fixes a wafer and the wafer height fine-tuning device is disposed between the exposure chuck and the wafer to adjust heights of a local area of the wafer.

In some embodiments, the exposure chuck includes an exposure chuck height adjustment device to adjust heights of the exposure chuck so as to further adjust heights of the wafer.

In some embodiments, the wafer height fine-tuning device includes a plurality of inverse piezoelectric devices directly contacting the wafer to respectively adjust the heights of the local area of the wafer.

In some embodiments, the size of the inverse piezoelectric devices is about 0.1 mm*0.1 mm to 5 mm*5 mm.

In some embodiments, an adjustment height of the inverse piezoelectric devices is about −100 nm to +100 nm.

In some embodiments, an adjustment height accuracy of the inverse piezoelectric devices is 1 nm.

In some embodiments, the exposure apparatus further includes a plurality of scanning sensors to detect heights of the local area of the wafer to obtain wafer height data.

In some embodiments, the exposure apparatus further includes a height analysis module connected to the scanning sensors to analyze the wafer height data to obtain an analysis result.

In some embodiments, the exposure apparatus further includes a chuck height control module connected to the height analysis module to adjust heights of the exposure chuck and the heights of the wafer according to the analysis result of the height analysis module.

In some embodiments, the exposure apparatus further includes a fine-tuning control module connected to the chuck height control module to respectively adjust heights of the inverse piezoelectric devices according to the analysis result of the height analysis module so as to respectively adjust the heights of the local area of the wafer.

According to another aspect of the present disclosure, an exposure apparatus control method including the steps of providing an exposure chuck and fixing a wafer on the exposure chuck. In addition, a wafer height fine-tuning device is further disposed between the exposure chuck and the wafer to adjust heights of a local area of the wafer.

In some embodiments, the exposure apparatus control method further includes steps of moving the wafer and detecting heights of the local area of the wafer.

In some embodiments, the exposure apparatus control method further includes utilizing an exposure chuck height adjustment device to adjust heights of the exposure chuck.

In some embodiments, the exposure apparatus control method further includes utilizing a wafer height fine-tuning device to adjust the heights of the local area of the wafer.

In some embodiments, the exposure apparatus control method further includes exposing the local area of the wafer.

In some embodiments, the wafer height fine-tuning device includes a plurality of inverse piezoelectric devices directly contacting the wafer to respectively adjust the heights of the local area of the wafer.

In some embodiments, the exposure apparatus control method further includes utilizing a plurality of scanning sensors to detect heights of the local area of the wafer to obtain wafer height data.

In some embodiments, the exposure apparatus control method further includes utilizing a height analysis module to analysis the wafer height data to obtain an analysis result.

In some embodiments, the exposure apparatus control method further includes utilizing a chuck height control module to adjust heights of the exposure chuck according to the analysis result of the height analysis module so as to further adjust the heights of the wafer.

In some embodiments, the exposure apparatus control method further includes utilizing a fine-tuning control module to respectively adjust heights of the inverse piezoelectric devices according to the analysis result of the height analysis module so as to respectively adjust the heights of the local area of the wafer.

Hence, the exposure apparatus and the control method thereof may effectively scan the heights of the local area of the wafer by the scanning sensors, adjust the heights of the exposure chuck and the heights of the entire wafer by the exposure chuck height adjustment device, and respectively adjust the local heights of the wafer by the wafer height fine-tuning device so as to effectively improve the precision and accuracy of semiconductor devices during the wafer exposure and further improve the quality and yield of the semiconductor devices.

It is to be understood that both the foregoing general description and the following detailed description are by examples, and are intended to provide further explanation of the disclosure as claimed.

The features, aspects, and advantages of the present disclosure are better understood by referring to the following detailed description. It is noted that both the foregoing general description and the following detailed description are merely illustrative and are intended to provide further explanations of the appended claims.

### BRIEF DESCRIPTION OF THE DRAWINGS

The present disclosure is best understood from the following detailed description and the accompanying figures. It is noted that the elements in the figures may not be drawn to meet the exact scale. Some elements may be drawn with increased or decreased sizes for clarity of the discussion.

FIG. 1 is a schematic diagram of an exposure apparatus according to an embodiment of the present disclosure; and

FIG. 2 is a schematic flowchart of an exposure apparatus control method according to an embodiment of the present disclosure.

### DETAILED DESCRIPTION

To make the description of the present disclosure more detailed and complete, explanatory descriptions of the aspects and specific implementations of the embodiments are provided below. It is not to limit the embodiments of the present disclosure to only one form. The embodiments of the present disclosure can combine or be substituted with each other under beneficial circumstances. Other embodiments may be appended without further description or explanation.

Furthermore, spatially relative terms, such as below and above, etc., may be used in the present disclosure to describe the relationship of one element or feature to another element or feature in the drawings. In addition to the orientation depicted in the figures, spatially relative terms are intended to encompass different orientations of the device in use or step. For example, the device may be otherwise oriented (e.g., rotated 90 degrees or otherwise) and the spatially relative terms of this disclosure are to be interpreted accordingly. In this disclosure, unless otherwise indicated, the same element numbers in different figures refer to the same or similar elements formed from the same or similar materials by the same or similar methods.

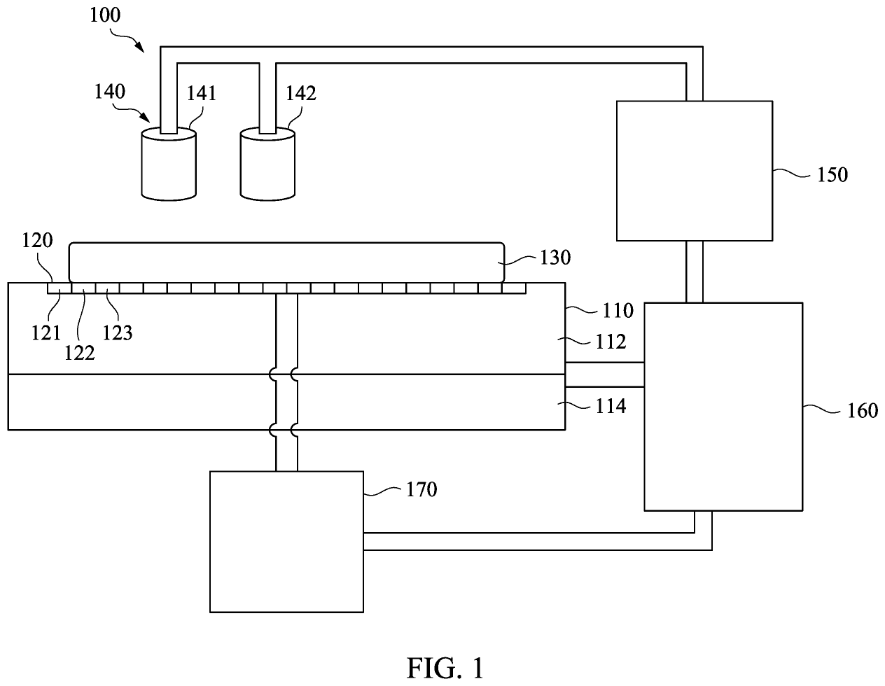

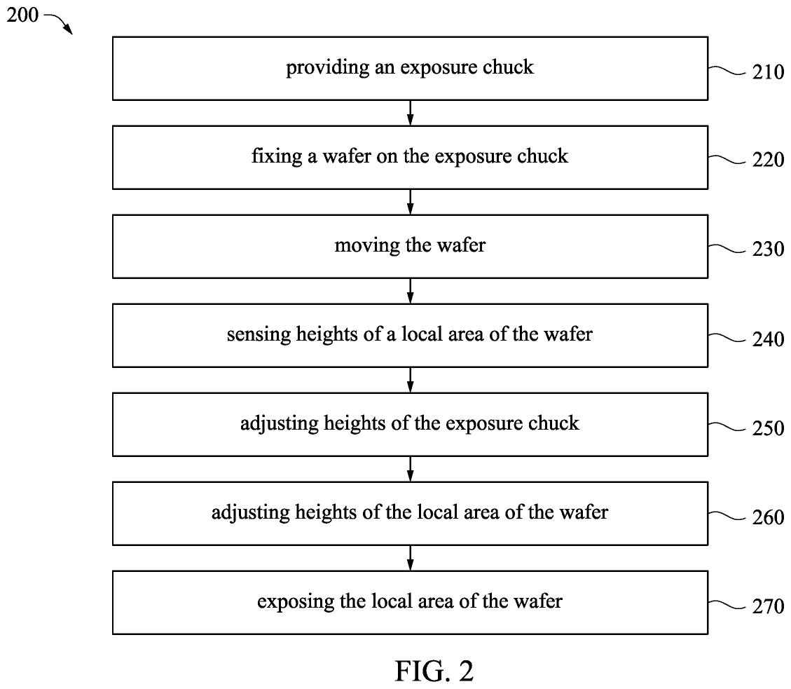

FIG. 1 is a schematic diagram of an exposure apparatus according to an embodiment of the present disclosure and FIG. 2 is a schematic flowchart of an exposure apparatus control method according to an embodiment of the present disclosure.

Referring to FIG. 1, as shown in the drawing, the exposure apparatus 100 is utilized to form the required circuit structure on a wafer 130 during a wafer exposure process. The exposure apparatus 100 includes an exposure chuck 110 and a wafer height fine-tuning device 120. The exposure chuck 110 is utilized to fix the wafer 130. It is worth noting that the wafer height fine-tuning device 120 is disposed between the exposure chuck 110 and the wafer 130 to adjust heights of a local area of the wafer 130.

In addition, the exposure chuck 110 includes an exposure chuck height adjustment device 114 to adjust heights of the exposure chuck 110 so as to further adjust heights of the wafer 130.

In some embodiments, the exposure chuck 110 further includes a plurality of vacuum suction cups 112 disposed on the exposure chuck height adjustment device 114 to suck the wafer 130 so as to fix the wafer 130 on the exposure chuck 110 to further process the wafer 130.

In some embodiments, the wafer height fine-tuning device 120 includes a plurality of inverse piezoelectric devices, e.g. a first inverse piezoelectric device 121, a second inverse piezoelectric device 122, a third inverse piezoelectric device 123, etc. The inverse piezoelectric devices directly contact the wafer 130 to respectively adjust heights of corresponding parts of the local area of the wafer 130.

In some embodiments, when appropriate voltages are applied, the first inverse piezoelectric device 121 and the second inverse piezoelectric device 122 push corresponding parts of the wafer 130 upward, and the third inverse piezoelectric device 123 moves downward, in conjunction with the downward force of the vacuum suction cups 112, to cause a corresponding part of the wafer 130 to move downward, and therefore the heights of the corresponding parts of the local area of the wafer 130 are adjusted according to the measurement results of the surface height of the wafer 130 so that the exposure light may be accurately focused on the surface of the wafer 130.

In some embodiments, the inverse piezoelectric devices of the wafer height fine-tuning device 120 are preferably distributed on the entire surface of the exposure chuck 110 to respectively and locally fine-tune the surface height of the wafer 130 fixed on the exposure chuck 110.

In some embodiments, the inverse piezoelectric devices of the wafer height fine-tuning device 120 and the vacuum suction cups 112 of the exposure chuck 110 are preferably staggered to effectively locally fine-tune the surface heights of the wafer 130.

In some embodiments, the vacuum suction cups 112 of the exposure chuck 110 may be replaced with the electrostatic suction cups, without departing from the spirit and protection scope of the present disclosure.

In some embodiments, the size of the first inverse piezoelectric device 121, the second inverse piezoelectric device 122 and the third inverse piezoelectric device 123 is about 0.1 mm*0.1 mm to 5 mm*5 mm, but not limited thereto.

In some embodiments, the adjustment height of the first inverse piezoelectric device 121, the second inverse piezoelectric device 122 and the third inverse piezoelectric device 123 is about −100 nm to +100 nm, but not limited thereto.

In some embodiments, the adjustment height accuracy of the first inverse piezoelectric device 121, the second inverse piezoelectric device 122 and the third inverse piezoelectric device 123 is 1 nm, but not limited thereto.

In some embodiments, the exposure apparatus 100 further includes a plurality of scanning sensors 140, e.g. a first scanning sensor 141, a second scanning sensor 142, etc., to detect heights of the local area of the wafer 130 to obtain a plurality of wafer height data.

In some embodiments, the exposure apparatus 100 further includes a height analysis module 150 connected to the scanning sensors 140 to analyze the wafer height data so as to obtain an analysis result.

In some embodiments, the exposure apparatus 100 further includes a chuck height control module 160 connected to the height analysis module 150 to adjust the heights of the exposure chuck 110 so as to further adjust the heights of the entire wafer 130 according to the analysis result of the height analysis module 150.

In some embodiments, the exposure apparatus 100 further includes a fine-tuning control module 170 connected to the chuck height control module 160 to respectively adjust the heights of the inverse piezoelectric devices so as to respectively adjust corresponding local parts of the local area of the wafer 130 according to the analysis result of the height analysis module 150.

That is to say, the exposure apparatus 100 may adjust the entire heights of the wafer 130 by adjusting the heights of the exposure chuck 110 and adjust corresponding local parts of a local area of the wafer 130 by respectively adjusting the heights of the inverse piezoelectric devices to accurately adjust the surface heights of the wafer 130 so as to precisely focus thereon.

Simultaneously referring to FIG. 2 and FIG. 1, an exposure apparatus control method 200 includes the following steps. In step 210, an exposure chuck 110 is provided. In step 220, a wafer 130 is fixed on the exposure chuck 110. In addition, a wafer height fine-tuning device 120 is equipped between the exposure chuck 110 and the wafer 130 to adjust heights of the local area of the wafer 130.

In some embodiments, the exposure apparatus control method 200 further includes a step 230 of moving the wafer 130, and a step 240 of sensing heights of the local area of the wafer 130. In addition, the wafer 130 is sucked on the exposure chuck 110 to horizontally move together with the exposure chuck 110. Furthermore, the step 240 of sensing heights of the local area of the wafer 130 may utilize a plurality of scanning sensors 140 to respectively detect the heights of the local area of the wafer 130 to obtain a plurality of wafer height data. In some embodiments, a plurality of scanning sensors 140 includes a first scanning sensor 141, a second scanning sensor 142, etc., and the scanning sensors 140 may move relative to the wafer 130 to detect the surface heights of the wafer 130 before the wafer 130 is exposed.

In some embodiments, in step 250, the exposure apparatus control method 200 may further include utilizing an exposure chuck height adjustment device 114 to adjust heights of the exposure chuck 110 and simultaneously adjust the heights of the entire wafer 130.

In some embodiments, in step 260, the exposure apparatus control method 200 may further include utilizing a wafer height fine-tuning device 120 to respectively adjust heights of the local area of the wafer 130.

In some embodiments, in step 270, the exposure apparatus control method 200 may further include respectively exposing the local area of the wafer 130. In addition, another local area of the wafer 130 is further detected, adjusted and exposed until the entire wafer 130 is exposed.

In some embodiments, a plurality of inverse piezoelectric devices respectively directly contact the wafer 130 to respectively adjust the heights of the local area of the wafer 130.

In some embodiments, a plurality of scanning sensors 140 are equipped in front of the exposing element, e.g. exposing lens, to pre-detect heights of the local area of the wafer 130. In addition, the exposure apparatus control method 200 utilizes a height analysis module 150 to analyze the wafer height data to obtain an analysis result. Furthermore, the analysis result is sent to the chuck height control module 160 and the fine-tuning control module 170.

In addition, the chuck height control module 160 may adjust the heights of the exposure chuck 110 and further adjust the heights of the wafer 130 according to the analysis result of the height analysis module 150. Furthermore, the fine-tuning control module 170 is utilized to further respectively adjust the heights of the inverse piezoelectric devices according to the analysis results of the height analysis module 150 to respectively adjust the local height of the corresponding local area of the wafer 130 so that the surface heights of the wafer 130 in the local area tend to be uniform to improve precision and accuracy during the exposure process.

Accordingly, the exposure apparatus and the control method thereof may effectively scan the heights of the local area of the wafer by the scanning sensors, adjust the heights of the exposure chuck and the heights of the entire wafer by the exposure chuck height adjustment device, and respectively adjust the local heights of the wafer by the wafer height fine-tuning device so as to effectively improve the precision and accuracy of semiconductor devices during the wafer exposure and further improve the quality and yield of the semiconductor devices.

The present disclosure is described in considerable detail with some embodiments. Other embodiments may be feasible. Therefore, the scope and spirit of the claims that are appended should not be limited to the description of the embodiments in the present disclosure.

For one skilled in the art, the present disclosure may be modified and changed as long as not departing from the spirit and scope of the present disclosure. If the modifications and changes are within the scope and spirit of the claims that are appended, they are covered by the present disclosure.

What is claimed is:

1. An exposure apparatus, comprising:
an exposure chuck to fix a wafer; and
a wafer height fine-tuning device disposed between the exposure chuck and the wafer to adjust heights of a local area of the wafer.

2. The exposure apparatus according to claim 1, wherein the exposure chuck comprises an exposure chuck height adjustment device to adjust heights of the exposure chuck so as to further adjust heights of the wafer.

3. The exposure apparatus according to claim 2, wherein the wafer height fine-tuning device comprises a plurality of inverse piezoelectric devices directly contacting the wafer to respectively adjust the heights of the local area of the wafer.

4. The exposure apparatus according to claim 3, wherein a size of one of the inverse piezoelectric devices is about 0.1 mm*0.1 mm to 5 mm*5 mm.

5. The exposure apparatus according to claim 4, wherein an adjustment height of one of the inverse piezoelectric devices is about −100 nm to +100 nm.

6. The exposure apparatus according to claim 5, wherein an adjustment height accuracy of the one of the inverse piezoelectric devices is 1 nm.

7. The exposure apparatus according to claim 3, further comprising:
a plurality of scanning sensors to detect heights of the local area of the wafer to obtain a plurality of wafer height data.

8. The exposure apparatus according to claim 7, further comprising:
a height analysis module connected to the scanning sensors to analyze the wafer height data to obtain an analysis result.

9. The exposure apparatus according to claim 8, further comprising:
a chuck height control module connected to the height analysis module to adjust heights of the exposure chuck according to the analysis result of the height analysis module so as to further adjust the heights of the wafer.

10. The exposure apparatus according to claim 9, further comprising:
a fine-tuning control module connected to the chuck height control module to respectively adjust heights of the inverse piezoelectric devices according to the analysis result of the height analysis module so as to respectively adjust the heights of the local area of the wafer.

11. An exposure apparatus control method, comprising:
providing an exposure chuck; and
fixing a wafer on the exposure chuck, wherein a wafer height fine-tuning device is further disposed between the exposure chuck and the wafer to adjust heights of a local area of the wafer.

12. The exposure apparatus control method according to claim 11, further comprising:
moving the wafer; and
detecting heights of the local area of the wafer.

13. The exposure apparatus control method according to claim 12, further comprising:
utilizing an exposure chuck height adjustment device to adjust heights of the exposure chuck.

14. The exposure apparatus control method according to claim 13, further comprising:
utilizing a wafer height fine-tuning device to adjust the heights of the local area of the wafer.

15. The exposure apparatus control method according to claim 14, further comprising:
exposing the local area of the wafer.

16. The exposure apparatus control method according to claim 15, wherein the wafer height fine-tuning device comprises a plurality of inverse piezoelectric devices directly contacting the wafer to respectively adjust the heights of the local area of the wafer.

17. The exposure apparatus control method according to claim 16, further comprising:
utilizing a plurality of scanning sensors to detect heights of the local area of the wafer to obtain a plurality of wafer height data.

18. The exposure apparatus control method according to claim 17, further comprising:
utilizing a height analysis module to analysis the wafer height data to obtain an analysis result.

19. The exposure apparatus control method according to claim 18, further comprising:
utilizing a chuck height control module to adjust heights of the exposure chuck according to the analysis result of the height analysis module so as to further adjust the heights of the wafer.

20. The exposure apparatus control method according to claim 19, further comprising:
utilizing a fine-tuning control module to respectively adjust heights of the inverse piezoelectric devices according to the analysis result of the height analysis module so as to respectively adjust the heights of the local area of the wafer.
